(19) United States
(12) Patent Application Publication
(10) Pub. No.: US 2025/0313950 A1
(43) Pub. Date: Oct. 9, 2025

(54) PRECURSOR, GAS MIXTURE, AND METHOD FOR DEPOSITING A LOW K DIELECTRIC FILM

(71) Applicant: Applied Materials, Inc., Santa Clara, CA (US)

(72) Inventors: Lakmal C. KALUTARAGE, San Jose, CA (US); Lauren Mary BAGBY, Palo Alto, CA (US); Michael HAVERTY, Santa Clara, CA (US); Bo XIE, San Jose, CA (US); Chi-I LANG, Cupertino, CA (US); Bhaskar SOMAN, Santa Clara, CA (US); Rui LU, Santa Clara, CA (US); Kent Qiujing ZHAO, San Francisco, CA (US); Li-Qun XIA, Cupertino, CA (US); Shankar VENKATARAMAN, San Jose, CA (US)

(21) Appl. No.: 19/173,421

(22) Filed: Apr. 8, 2025

Related U.S. Application Data
(60) Provisional application No. 63/631,672, filed on Apr. 9, 2024.

(51) Int. Cl. C23C 16/32; C23C 16/505

(52) U.S. Cl. CPC C23C 16/325; C23C 16/505

(57) ABSTRACT

Disclosed herewith are a precursor, a gas mixture, and a method for depositing a dielectric film in a processing chamber. A method includes disposing a substrate on a susceptor disposed within a processing chamber; controlling a pressure level and a temperature of the processing chamber; delivering an RF power into the processing chamber; providing a precursor-containing gas mixture into the processing chamber, and applying a post-deposition process to the substrate after the dielectric film is formed on the substrate. The precursor-containing gas mixture includes a precursor and an inert gas selected from the group consisting of argon, nitrogen, and helium. The precursor includes a carbosilane having a Si—C—Si structure in a backbone of the precursor.

### CROSS-REFERENCE TO RELATED APPLICATIONS

This application claims benefit of U.S. Provisional Application Ser. No. 63/631,672 filed Apr. 9, 2024 (Attorney Docket No. APPM/44022915US01), of which is incorporated by reference in its entirety.

### FIELD

The present disclosure generally relates to a precursor, a gas mixture, and a method for depositing a low K dielectric film on a substrate, and, more particularly, relates to depositing a low K dielectric film by using a precursor including a Si—C—Si structure.

### BACKGROUND

The development of semiconductor devices continuously demands smaller dimensions, larger data capacity, and faster processing speed. To meet the performance demands of these semiconductor devices, insulating layers that separate other layers need to have a low dielectric constant k (less than three (3)) to reduce a possible resistance-capacitance delay. These insulating layers may include intermetal dielectric films (IMD), interlayer dielectric films (ILD), or other insulating layers. Not only these insulating layers isolate other layers, they also provide a mechanical support to other layers. However, current methods and precursors utilized to deposit a low dielectric constant film often result in poor mechanical properties.

Thus, there is a need for an improve precursor and method for forming a low dielectric constant film on a substrate.

### SUMMARY

Disclosed herewith are a precursor, a gas mixture, and a method for depositing a dielectric film in a processing chamber. In an example, the precursor includes a carbosilane comprising a Si—C—Si structure in a backbone of the precursor. The precursor may include additional functional groups linked with the silicon atom. The gas mixture includes the precursor and an inert gas selected from the group consisting of argon, nitrogen, and helium. The gas mixture may further include an oxidizing gas.

In an example, the method includes disposing a substrate on a susceptor disposed within a processing chamber; controlling a pressure level and a temperature of the processing chamber; delivering an RF power into the processing chamber; providing a precursor-containing gas mixture into the processing chamber, and applying a post-deposition process to the substrate after the dielectric film is formed on the substrate. The precursor-containing gas mixture includes the precursor as set forth various embodiments of the present disclosure and an inert gas selected from the group consisting of argon, nitrogen, and helium. Other process gases, such as an oxidizing gas, may be included in the precursor-containing gas mixture. The method may further include soaking a deposited dielectric film in a soaking gas in-between depositions or after the deposition.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic top view of a processing system, according to an embodiment of the present disclosure.

FIG. 2 illustrates a schematic cross-sectional view of a processing chamber for depositing a dielectric constant film on a substrate, according to an embodiment of the present disclosure.

FIG. 3 illustrates a method for forming a low k dielectric film in a processing chamber, according to one or more embodiments of the present disclosure.

FIG. 4A illustrates a structure of a carbosilane precursor with a backbone having two silicon and one carbon, according to one or more embodiments of the present disclosure.

FIG. 4B illustrates another structure of a carbosilane precursor with a backbone having two silicon and one carbon, according to one or more embodiments of the present disclosure.

FIG. 5A illustrates a structure of a carbosilane precursor with a backbone having three silicon and one carbon, according to one or more embodiments of the present disclosure.

FIG. 5B illustrates another structure of a carbosilane precursor with a backbone having three silicon and one carbon, according to one or more embodiments of the present disclosure.

FIG. 6A illustrates a structure of a carbosilane precursor with a backbone having three silicon and two carbon, according to one or more embodiments of the present disclosure.

FIG. 6B illustrates another structure of a carbosilane precursor with a backbone having three silicon and two carbon, according to one or more embodiments of the present disclosure.

FIG. 7A illustrates a structure of a carbosilane precursor with a backbone having four silicon and two carbon, according to one or more embodiments of the present disclosure.

FIG. 7B illustrates a structure of a carbosilane precursor with a backbone having four silicon and two carbon, according to one or more embodiments of the present disclosure.

FIG. 8 illustrates a method for depositing a dielectric film, according to an embodiment of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Disclosed here are a precursor, a gas mixture containing the precursor, and a method for forming a dielectric film having a low dielectric constant (k) and a high hardness (H). In an example, the precursor includes carbosilane having a Si—C—Si structure in the backbone. The carbosilane may include two, three, four, or even more number of silicon atoms. The backbone of the carbosilane may be linear, cyclic, or the combination thereof. The silicon atom may be linked with a functional group for crosslinking, pore generation, or other suitable function. The functional group may be hydrogen (H) or selected from alkyl groups having from one (1) to four (4) carbon atoms. The functional group may include an oxygen atom, a nitrogen atom, a sulfur atom, a chlorine atom, a fluorine atom, or other suitable atom. For example, the functional group may be selected from the group consisting of methyl (Me), methoxy (OMe), ethyl (Et), ethoxy (OEt), isopropyl (iPr), isoproproxy (OiPr), and tert-butyl (tBu). In an embodiment, an oxygen atom may be used to link the silicon atom with functional groups, such as hydrogen atom, Me, Et, iPr, and tBu. Other functional groups, such as OMe, OEt, and OiPr, may be directly linked to the silicon atom.

In addition to the carbosilane as set forth in the present disclosure, the precursor may include one or more other precursors. The one or more other precursors include a ring type siloxane, a linear type silane having a Si—O link, and a linear type siloxane having a Si—O—Si link. The ring type siloxane may be selected from the group consisting of octamethylcyclotetrasiloxane, 2,4,6,8-tetramethyl-2,4,6,8-tetravinylcyclotetrasiloxane, and 2,4,6,8-tetramethylcyclotetrasiloxane. The linear type silane having a Si—O link may be selected from the group consisting of dimethyldimethoxysilane, ethoxydimethylsilane, isobutylmethyldimethoxysilane, and vinylmethyldimethoxysilane. The linear type silane having a Si—O—Si link may be selected from the group consisting of 1,1,3,3-tetramethyl-1,3-dimethoxydisiloxane and 1,3-dimethyl-1,1,3,3-tetramethoxydisiloxane. When the precursor includes a carbosilane and one or more other precursor, the carbosilane in the precursor may account for at least a majority of the precursor, such as between about 50% and about 90% of the flow rate of the precursor.

In another example, the gas mixture for depositing a dielectric film includes one or more precursors as described in various embodiments of the present disclosure. The gas mixture may additionally include an inert gas and an oxidizing gas.

In another example, the method of depositing a dielectric film on a substrate provides the gas mixture into a processing chamber, such as a PECVD chamber. An RF power can be used to energize and maintain a plasma in the processing chamber during deposition. After deposition, the dielectric film may further undergo an annealing process, a UV cure process, or both. The post-deposition process may be implemented in the presence of a process gas selected from the group consisting of an inert gas, a hydrocarbon gas, NH₃, and an oxidizing gas. In an embodiment, a chemical soaking process may be implemented after deposition or in-between depositions to adjust the structures of the dielectric film, such as crosslinking, bond density, or incorporation of selected atoms.

The dielectric film deposited according to various embodiment of the present disclosure may have a dielectric constant value k of about 3.0 or less, such as about 2.7 or less. The dielectric film may also have a hardness value H of at least about 2.0 GPa, at least about 4.0 GPa, or at least about 5.0 GPa. Thus, the dielectric film of the present disclosure can have both a low dielectric constant and an improved mechanical property for being used as an insulating layer in a semiconductor device.

Many of the details, dimensions, angles and other features shown in the Figures are merely illustrative of particular embodiments. Accordingly, other embodiments can have other details, components, dimensions, angles and features without departing from the spirit or scope of the present disclosure. In addition, further embodiments of the disclosure can be practiced without several of the details described below.

A “substrate,” “substrate surface,” or the like, as used herein, refers to any substrate or material surface formed on a substrate upon which processing is performed. For example, a substrate surface on which processing can be performed include, but are not limited to, materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what materials are to be deposited, as well as the particular chemistry used.

As used in this specification and the appended claims, the terms “precursor compound,” “precursor gas,” “precursor species,” “precursor,” “precursor gas,” and the like are used interchangeably to include at least a substance with a species capable of forming a material on the substrate surface in a surface reaction.

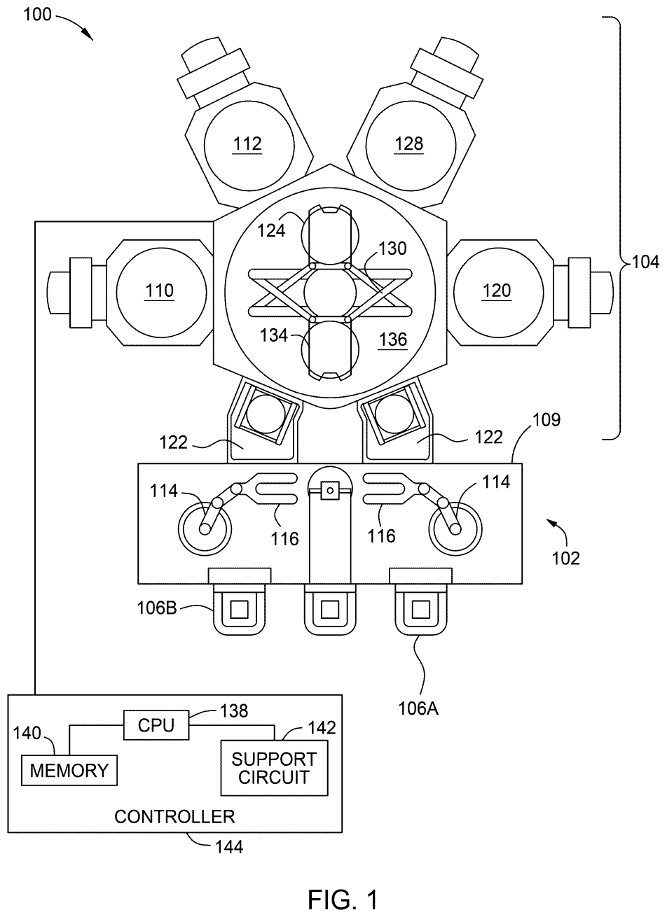

FIG. 1 illustrates a schematic top view of a processing system 100 for depositing a dielectric film on a substrate, according to one or more embodiments. The processing system 100 is configured to implement the method to form a dielectric film according to various embodiments of the present disclosure. The processing system 100 includes a processing platform 104 coupled with a factoring interface 102 and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, one or more load lock chambers 122, and a transfer chamber 136 that is coupled to the one or more load lock chamber 122. The plurality of processing chamber 110 may include a plasma enhanced chemical vapor deposition (PECVD) chamber, an epitaxy (EPI) chamber, a rapid thermal processing (RTP) chamber, a reactive ion etching (RIE) chamber, or other suitable chamber. The transfer chamber 136 can be maintained under vacuum, or can be maintained at an ambient (e.g., atmospheric) pressure. Two load lock chambers 122 are shown in FIG. 1.

Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The factory interface 102 is coupled to the transfer chamber 136 through the load lock chambers 122. In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers.

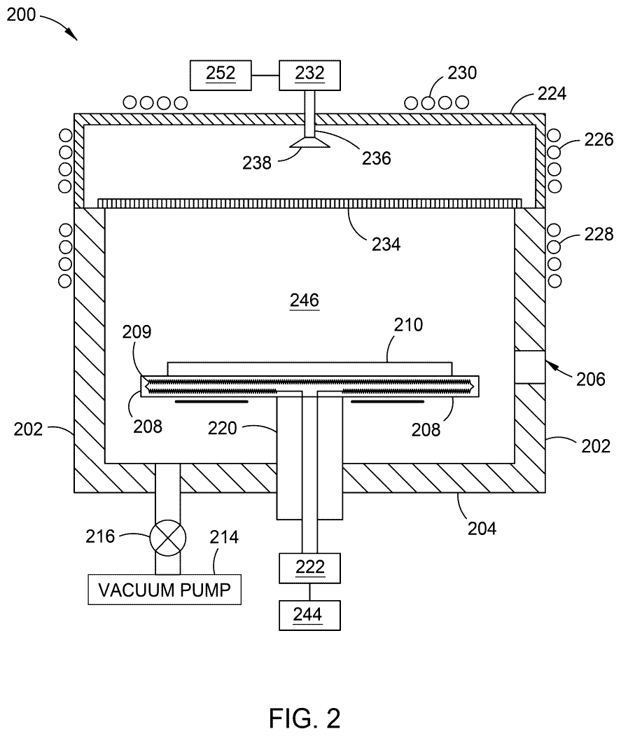

FIG. 2 illustrates a processing chamber 200, according to an embodiment. The processing chamber 200 may be a PECVD chamber configured to deposit a dielectric film on a substrate 210 according to various embodiment of the present disclosure. At least one of the processing chambers 110, 112, 120, 128 of FIG. 1 may be configured as the processing chamber 200. The processing chamber 200 in FIG. 2 includes side walls 202, a bottom 204, a chamber lid 224, and a lower wall liner 248. The chamber lid 224, the side walls 202, and the bottom 204 together enclose a processing region 246. A susceptor 208 is disposed in the processing region 246 and supports the substrate 210 thereon during processing. The side walls 202 include a plurality of ports 206 for transferring the substrate 210 in or out of the processing chamber 200.

The processing chamber 200 further includes a vacuum pump 214 and a plurality of gas sources 232 configured to provide a plurality of process gases into the processing chamber 200. The plurality of process gases may include a precursor gas, an inert gas, an oxidizing gas, a purge gas, and other suitable gas. A remote plasma source 252 may be coupled with the gas sources 232 and configured to energize the process gas independently or energize a mixture of two or more of the process gases. The energized process gas is provided to the process chamber 200 via a top baffle 236. The vacuum pump 214 is coupled to the processing chamber 200 and configured to adjust the vacuum level within the process region 246 via a valve 216. The vacuum pump 214 is also configured to evacuate spent gases from the processing chamber 200.

The processing chamber 200 may include a gas plenum 238 contained between the lid 224 and a showerhead 234. The gas showerhead 234 includes a plurality of conduits that allow the process gases to flow through.

The processing chamber 200 includes one or more plasma sources 226, 228, 230 disposed at various locations of the processing chamber 200 to energize the process gases. As shown in FIG. 2, a plasma source 230 may be disposed at a top surface of the lid 224, and/or another plasma source 226 is disposed around the side walls of the lid 224. The plasma sources 230 and 226 are operable to energize the process gases above the showerhead 234, i.e. within the gas plenum 238. Another plasma source 228 may be disposed along side walls 202 and is operable to energize the process gases between the showerhead 234 and the susceptor 208. The plasma sources 252, 230, 226, and 228 can be controlled independently or collectively by the controller 114 depicted in FIG. 1.

The susceptor 208 may be part of a substrate support assembly 220, which includes an electrode 209 coupled with one or more power sources 222 and 244. The electrode 209 may be configured to heat the susceptor 208 and/or chuck the substrate 210 on the susceptor 208. In some examples, which may be combined with other examples, it is contemplated that the susceptor 208 may be any device capable of supporting a substrate 210 thereon and therefore may be heater other than by absorption of electromagnetic radiation.

The controller 144 is configured to control the plurality of gas sources 232, the plurality of plasma sources 226, 228, and 230, the vacuum pump 214, and the plurality of the power sources 222 and 224. The control 144 is capable of controlling the flow rate of the process gases, the temperature of the susceptor, the pressure level of the processing chamber, and the RF power delivered into the processing chamber.

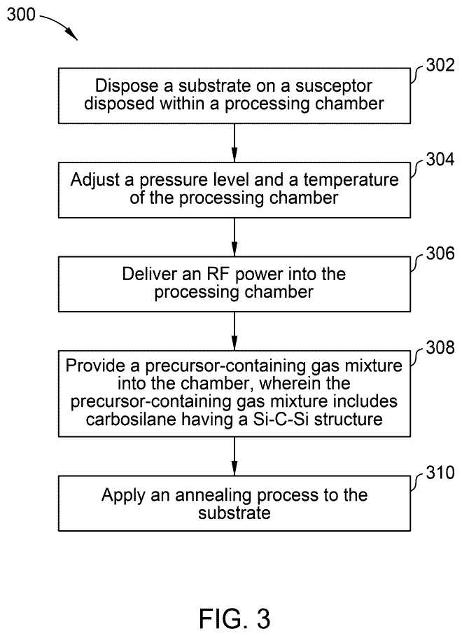

FIG. 3 illustrates a method 300 for depositing a dielectric film on a substrate, according to an embodiment of the present disclosure. The method 300 begins at operation 302 by positioning a substrate, such as a substrate 210 shown in FIG. 2, into the processing chamber 200. The substrate 210 may be positioned on the susceptor 208 and held by a chucking electrode. The substrate 210 may include a material such as crystalline silicon (e.g., Si (100) or Si (111)), silicon oxide, strained silicon, silicon germanium, doped or undoped polysilicon, doped or undoped silicon substrates and patterned or non-patterned substrates silicon on insulator (SOI), carbon doped silicon oxides, silicon nitride, doped silicon, germanium, gallium arsenide, glass, sapphire. The dielectric film of one or more embodiments may be formed on any surface or any portion of the substrate 210.

At operation 304, the pressure level in the processing volume 246 may be controlled to be between about 0.1 mTorr to about 100 Torr, or about 50 mTorr to about 50 Torr. The substrate temperature may be controlled to be between about 20° C. to about 500° C.

At operation 306, an RF power is delivered to the processing chamber by the plurality of plasma sources shown in FIG. 2. The RF power is configured to energize and maintain a plasma inside the processing chamber. The RF power may be between about 10 Watts and about 3000 Watts at a frequency in a range of from about 350 KHz to about 100 MHz. The RF power may be applied continuously or may be pulsed.

During operation 308, a precursor-containing gas mixture is flowed into the processing volume to form the dielectric film on the substrate 210. The precursor-containing gas mixture may include one or more precursor gases. At least one precursor gas includes a carbosilane having a Si—C—Si structure in the backbone. The precursor gas will be described in more detail in referring to other drawings of the present disclosure. A flow rate of the precursor gas may be between about 50 mg/min to about 10,000 mg/min. In an embodiment, the precursor gas may be provided into the processing chamber continuously or in a pulsing manner. In an embodiment, the precursor-containing gas mixture may contain other precursor gases, such as Si-based precursor gases containing Si, O, C, and H. In another example, the other precursor gas include a ring type siloxane, a linear type silane having a Si—O link, and a linear type siloxane having a Si—O—Si link. The ring type siloxane may be selected from the group consisting of octamethylcyclotetrasiloxane, 2,4,6,8-tetramethyl-2,4,6,8-tetravinylcyclotetrasiloxane, and 2,4,6,8-tetramethylcyclotetrasiloxane. The linear type silane having a Si—O link may be selected from the group consisting of dimethyldimethoxysilane, ethoxydimethylsilane, isobutylmethyldimethoxysilane, and vinylmethyldimethoxysilane. The linear type silane having a Si—O—Si link may be selected from the group consisting of 1,1,3,3-tetramethyl-1,3-dimethoxydisiloxane and 1,3-dimethyl-1, 1,3,3-tetramethoxydisiloxane.

The precursor-containing gas mixture may additionally include an oxidizing gas, such as O₂, N₂O, NO₂, CO, CO₂, or other oxidizing gas. In some embodiments, an inert gas, such as argon (Ar), helium (He), nitrogen (N₂) or other suitable inert gas, may be supplied with the precursor-containing gas mixture into the processing volume. Additionally, a variety of other processing gases may be added to the precursor-containing gas mixture to modify properties of the dielectric film. In one or more embodiments, the other processing gases may be reactive gases, such as hydrogen (H₂), ammonia (NH₃), a mixture of hydrogen (H₂) and nitrogen (N₂), or combinations thereof. The addition of H₂ and/or NH₃ may be used to control the hydrogen ratio of the deposited dielectric film.

In an embodiment, the plasma in the processing chamber may be energized before the precursor is delivered into the processing chamber. Alternatively, the plasma may be energized after the precursor is delivered into the processing chamber.

At operation 310, after the dielectric film formed on the substrate reaches a predetermined thickness, the substrate 210 and the dielectric film are subject to a post-deposition process. The post-deposition process may include an annealing process, a cure process, or other suitable process. For example, the substrate and the dielectric film can be annealed under vacuum, an inert gas, a hydrocarbon gas, NH₃, or an oxidizing gas. The substrate and the dielectric film may additionally undergo an UV cure process under vacuum, an inert gas, a hydrocarbon gas, NH₃, or an oxidizing gas. The post-deposition process is configured to induce additional cross-linking of the dielectric film, thus improving the mechanical property thereof.

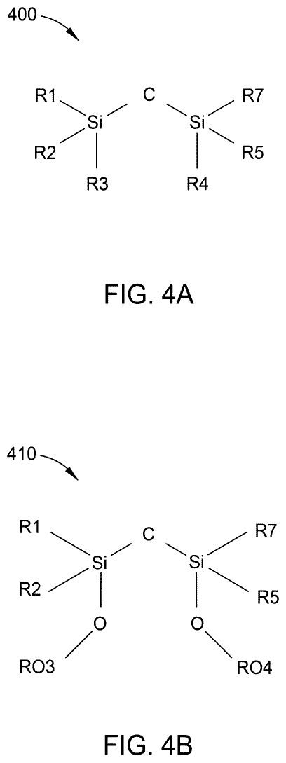

FIGS. 4A and 4B illustrate structures of a carbosilane precursor with a backbone having two silicon and one carbon, according to one or more embodiments. The carbosilane precursor 400 shown in FIG. 4A is represented by the following formula:

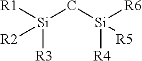

where: Si represents a silicon atom and C represents a carbon atom. Each functional group R1-R7 may be hydrogen (H) or selected from alkyl groups having from one (1) to four (4) carbon atoms. The functional group may include an oxygen atom, a nitrogen atom, a sulfur atom, a chlorine atom, a fluorine atom, or other suitable atom. For example, the functional group R1-R7 may be selected from the group consisting of methyl (Me), methoxy (OMe), ethyl (Et), ethoxy (OEt), isopropyl (iPr), isoproproxy (OiPr), and tert-butyl (tBu). Each silicon atom is linked with three functional groups R1-R7.

In an embodiment, one or more oxygen atoms may be used to link the silicon atom with the functional group. For example, as shown in FIG. 4B, the carbosilane precursor 410 includes the same Si—C—Si backbone as the precursor 400 of FIG. 4A. But, each of the silicon atom of the carbosilane precursor 410 includes one oxygen atom disposed between the silicon atom and a functional group, represented by the following formula:

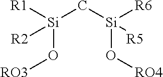

where O represents an oxygen atom, and each of RO3 and RO4 may include similar groups as the functional group R1-R7 of the precursor 400.

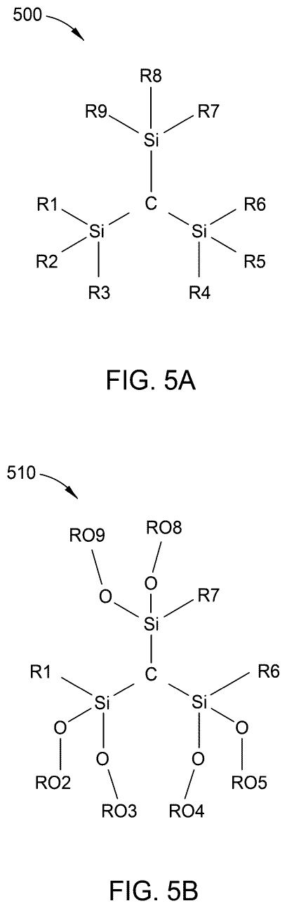

FIGS. 5A-B illustrate structures of a carbosilane precursor with a backbone having three silicon and one carbon, according to one or more embodiments. The carbosilane precursor 500 shown in FIG. 5A is represented by the following formula:

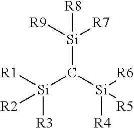

where: Si represents a silicon atom, and C represents a carbon atom. Each functional group R1-R9 may be hydrogen (H) or selected from alkyl groups having from one (1) to four (4) carbon atoms. The functional group may include an oxygen atom, a nitrogen atom, a sulfur atom, a chlorine atom, a fluorine atom, or other suitable atom. For example, the functional group R1-R9 may be selected from the group consisting of methyl (Me), methoxy (OMe), ethyl (Et), ethoxy (OEt), isopropyl (iPr), isoproproxy (OiPr), and tert-butyl (tBu). The carbosilane precursor 500 includes a star-shaped backbone having one carbon atom linked with three silicon atoms. Each silicon atom is linked with three functional groups R1-R9.

Similar as the precursor 410 shown in FIG. 4B, the carbosilane precursor 510 shown in FIG. 5B includes additional oxygen atoms linked with the silicon atoms. For example, each of the silicon atom of the carbosilane precursor 510 includes two oxygen atoms disposed between the silicon atom and a functional group, represented by the following formula:

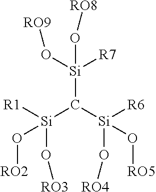

where O represents an oxygen atom and each of RO2-RO5, RO8, and RO9 may include similar groups as the functional groups R1-R9.

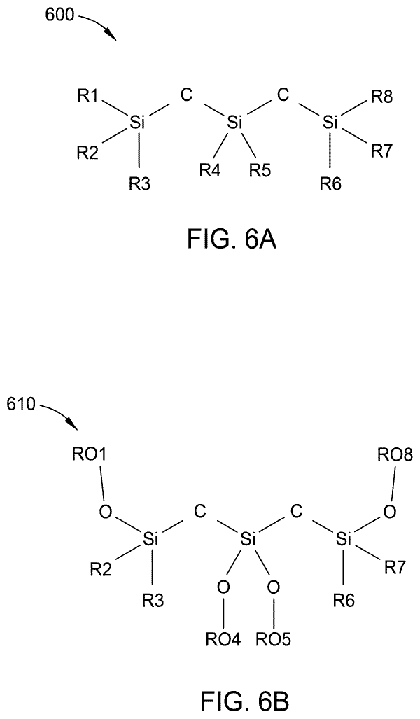

FIGS. 6A-B illustrate structures of a carbosilane precursor with a backbone having three silicon and two carbon, according to one or more embodiments. The carbosilane precursor 600 shown in FIG. 6A is represented by the following formula:

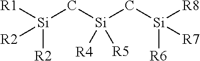

where: Si represents a silicon atom, and C represents a carbon atom. Each functional group R1-R8 may be hydrogen (H) or selected from alkyl groups having from one (1) to four (4) carbon atoms. The functional group may include an oxygen atom, a nitrogen atom, a sulfur atom, a chlorine atom, a fluorine atom, or other suitable atom. For example, the functional group R1-R8 may be selected from the group consisting of methyl (Me), methoxy (OMe), ethyl (Et), ethoxy (OEt), isopropyl (iPr), isoproproxy (OiPr), and tert-butyl (tBu). The carbosilane precursor 600 includes a linear backbone having two carbon atoms linked with three silicon atoms in an alternating manner. Each silicon atom is linked with two or three functional groups R1-R8.

Similar as the precursor 410 shown in FIG. 4B, the carbosilane precursor 610 shown in FIG. 6B includes additional oxygen atoms linked with the silicon atoms. For example, the silicon atoms at the two ends of the backbone of the carbosilane precursor 610 includes one oxygen atom disposed between the silicon atom and a functional group, while the silicon atom in the middle of the backbone are linked with two oxygen atoms. The carbosilane precursor 610 is represented by the following formula:

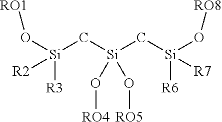

where O represents an oxygen atom, and each of the functional groups RO1, RO4, RO5, and RO8 may include similar groups as the functional groups R1-R8.

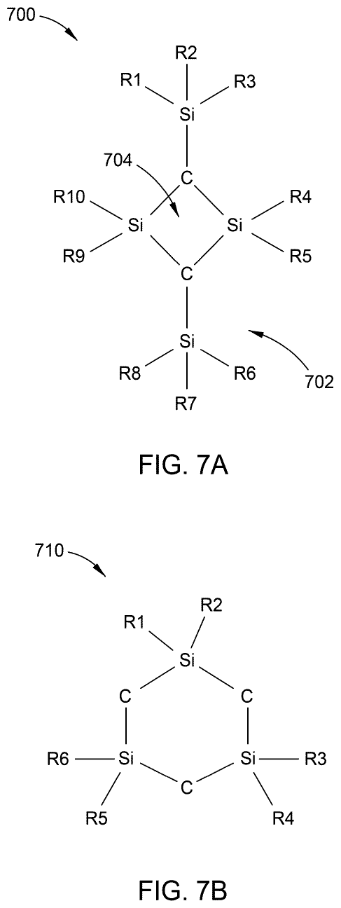

FIGS. 7A-B illustrate structures of a carbosilane precursor with a backbone having four silicon and two carbon, according to one or more embodiments. The carbosilane precursor 700 shown in FIG. 7A is represented by the following formula:

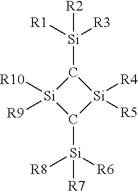

where: Si represents a silicon atom, and C represents a carbon atom. Each functional group R1-R10 may be hydrogen (H) or selected from alkyl groups having from one (1) to four (4) carbon atoms. The functional group may include an oxygen atom, a nitrogen atom, a sulfur atom, a chlorine atom, a fluorine atom, or other suitable atom. For example, the functional group R1-R10 may be selected from the group consisting of methyl (Me), methoxy (OMe), ethyl (Et), ethoxy (OEt), isopropyl (iPr), isoproproxy (OiPr), and tert-butyl (tBu). The carbosilane precursor 700 includes a backbone having two carbon atoms linked with four silicon atoms. Each carbon atom is linked with three silicon atoms. Each silicon atom is linked with two or three functional groups R1-R10. The backbone of the precursor 700 includes both a linear segment 702 and a cyclic segment 704 of Si—C—Si bonds.

As shown in FIG. 7B, the carbosilane precursor 710 has a cyclic backbone formed by three carbon atoms linked with three silicon atoms. Each silicon atom is linked with two functional groups R1-R6. The carbosilane precursor 710 is represented by the following formula:

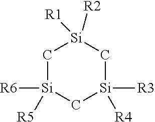

Each functional group R1-R6 may be hydrogen (H) or selected from alkyl groups having from one (1) to four (4) carbon atoms. The functional group may include an oxygen atom, a nitrogen atom, a sulfur atom, a chlorine atom, a fluorine atom, or other suitable atom. For example, the functional group R1-R6 may be selected from the group consisting of methyl (Me), methoxy (OMe), ethyl (Et), ethoxy (OEt), isopropyl (iPr), isoproproxy (OiPr), and tert-butyl (tBu).

In an example, the improved dielectric films were prepared by using the precursor shown in FIG. 4B with the following processing parameters: temperature: 300-450° C., pressure: 5 Torr-15 Torr, precursor flow: 200 mg/min-400 mg/min, RF power: 200-500 W, He flow: 400 sccm, and O2 flow: 0-10 sccm. The improved dielectric films have their dielectric constant values k between 2 and 3 with 90% of the dielectric constant values k less than about 2.7. Baseline dielectric films were prepared by using diethoxydimethylsilacyclobutane (EMSCB) with the following processing parameters: temperature: 310-400° C., pressure: 3 Torr-5 Torr, precursor flow: 150 mg/min-300 mg/min, RF power: 200-500 W, He flow: 350-450 sccm, and O2 flow: 0-30 sccm. The baseline dielectric films have their dielectric constant values between 3 and 4. The hardness values of the improved dielectric film and the baseline dielectric films are about the same, which fall between about 2.0 GPa and 10 GPa. An average of the hardness values is about 4.0 GPa.

In an embodiment, a precursor is formed by two or more precursors, one of which is a carbosilane as set forth in the present disclosure. Other precursors include a ring type siloxane, a linear type silane having a Si—O link, and a linear type siloxane having a Si—O—Si link. The ring type siloxane may be selected from the group consisting of octamethylcyclotetrasiloxane, 2,4,6,8-tetramethyl-2,4,6,8-tetravinylcyclotetrasiloxane, and 2,4,6,8-tetramethylcyclotetrasiloxane. The linear type silane having a Si—O link may be selected from the group consisting of dimethyldimethoxysilane, ethoxydimethylsilane, isobutylmethyldimethoxysilane, and vinylmethyldimethoxysilane. The linear type silane having a Si—O—Si link may be selected from the group consisting of 1,1,3,3-tetramethyl-1,3-dimethoxydisiloxane and 1,3-dimethyl-1,1,3,3-tetramethoxydisiloxane. When the precursor includes a carbosilane and one or more other precursor, the carbosilane in the precursor may account for at least a majority of the precursor, such as between about 50% and about 90% of the precursor.

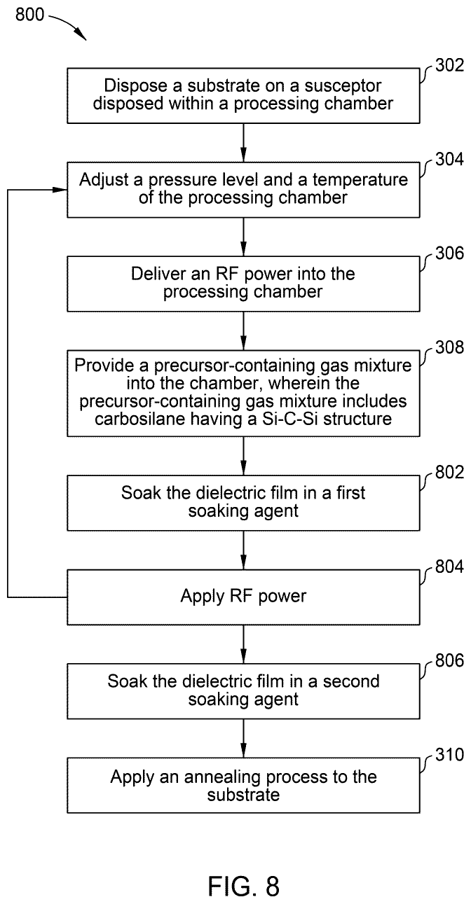

FIG. 8 illustrates a method 800 for depositing a dielectric film, according to an embodiment of the present disclosure. Comparing to the method 300, the method 800 includes two soaking processes: a mid-deposition soaking process 802 and a post deposition soaking process 804. The soaking processes 802 and 804 soak a deposited dielectric film in soaking gases configured to adjust chemical structures of the dielectric film, such as bond density, crosslinking, and incorporation of fluorine atoms into the film. As a result, the soaking process can lower the dielectric constant and increase the hardness of the dielectric film. The soaking process provides another tool to fine tune the targeted properties of the dielectric film.

Soaking, such as operations 802 and 804, is implemented in-between depositions of a dielectric film for an efficient treatment of the deposited dielectric film. As a thick film is more difficult to be penetrated by a soaking gas, the method 800 implements a soaking process each time the deposited dielectric film reaches a penetrating thickness. For example, each time the deposited dielectric film reaches about 300 to 500 angstroms, the soaking process will be implemented. As shown in FIG. 8, operations 302, 304, 306, and 308 of the method 800 are similar as those in the method 300, except that they only deposit a very think dielectric film, such as about 300 to 500 angstroms. Then, the soaking process, such as operations 802 and 804, is implemented. Once the soaking process is completed, the deposition process will be restarted, and additional dielectric film will be deposited. This deposition and soaking processes will reiterate until the deposited dielectric film reaches a desired thickness, such as 2,500 angstroms. In an embodiment, this mid-disposition soaking operation 802 can be implemented in the same chamber for depositing the dielectric film.

During operation 802, the RF power is stopped, and the deposition gas is replaced by a first soaking gas. The first soaking gas may include NF3 and argon gas, which provide fluorine atoms to the deposited dielectric film. The soaking time may be about 20 seconds to about 30 seconds depending on selected penetrating thickness. The temperature may be about the same as the deposition temperature. The pressure level may be maintained between about 4 Torr to about 20 Torr.

During operation 804, the first soaking gas is replaced by a helium gas, and then the RF power is turned on for about 10 seconds to about 15 seconds. The RF power may be set between about 100 W to 1000 W. At the end of the operation 804, the method 800 returns to operation 304 to deposit an additional thickness of the dielectric film. The operations from 304 to 804 reiterate until the dielectric film reaches a desired thickness. Then, the method goes to operation 806.

At operation 806, an optional post-deposition soaking process is implemented. In an embodiment, operation 806 may be implemented in the same deposition chamber of in a different chamber if a second soaking gas is used, which may be incompatible with the first soaking gas. The second soaking gas may include any one gas selected from the group consisting of NF₃, a carbon containing chemical (C₂H₄, CF₄ or Hexane), O₃, or NH₃. The temperature and pressure may be the same as the mid-deposition soaking process. The soaking period of operation 806 may be about 60 seconds or longer. After operation 806, operation 310 that is similar as that of method 300 may be included in the method 800.

Overall, the present disclosure provides methods of preparing thin, low dielectric constant films from various carbosilane precursors. In particular, dielectric films of the present disclosure were formulated from compounds having Si—C—Si bonds. It was found that films formed from methods and carbosilane precursors disclosed herein exhibit improved mechanical properties over films formed from other precursors using similar processing and fabrication methods, without detriment to the dielectric constant value.

The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the present disclosure, additionally, they do not exclude impurities and variances normally associated with the elements and materials used.

Numerical ranges used herein include the numbers recited in the range. For example, the numerical range “from 1 wt % to 10 wt %” includes 1 wt % and 10 wt % within the recited range.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

All documents described herein are incorporated by reference herein, including any priority documents and or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the present disclosure has been described with respect to a number of embodiments and examples, those skilled in the art, having benefit of this disclosure, will appreciate that other embodiments can be devised which do not depart from the scope and spirit of the present disclosure.

What is claimed is:

1. A precursor for forming a dielectric film, the precursor comprising a carbosilane comprising a Si—C—Si structure in a backbone of the precursor.

2. The precursor of claim 1, wherein the carbosilane comprises a structure represented by a formula: 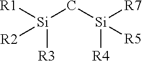
where Si represents a silicon atom, C represents a carbon atom, and each of R1-R7 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

3. The precursor of claim 2, wherein the carbosilane comprises a structure represented by a formula: 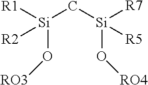
where O represents an oxygen atom, and RO2 or RO4 represents a functional group selected from a group consisting of hydrogen (H), methyl (Me), ethyl (Et), isopropyl (iPr), and tert-butyl (tBu).

4. The precursor of claim 1, wherein the carbosilane comprises a structure represented by a formula: 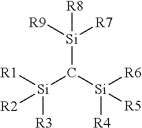
where Si represents a silicon atom, C represents a carbon atom, and each of R1-R9 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

5. The precursor of claim 4, wherein the carbosilane comprises a structure represented by a formula: 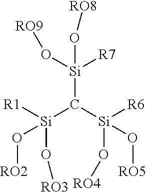
where O represents an oxygen atom, and each of RO2-RO5, RO8, and RO9 represents a functional group selected from a group consisting of hydrogen (H), methyl (Me), ethyl (Et), isopropyl (iPr), and tert-butyl (tBu).

6. The precursor of claim 1, wherein the carbosilane comprises a structure represented by a formula: 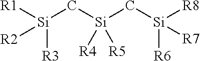
where Si represents a silicon atom, C represents a carbon atom, and each of R1-R8 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

7. The precursor of claim 1, further comprising one or more precursors selected from the group consisting of a ring type siloxane, a linear type silane having a Si—O link, and a linear type siloxane having a Si—O—Si link, wherein the ring type siloxane is selected from the group consisting of octamethylcyclotetrasiloxane, 2,4,6,8-tetramethyl-2,4,6,8-tetravinylcyclotetrasiloxane, and 2,4,6,8-tetramethylcyclotetrasiloxane, the linear type silane having the Si—O link is selected from the group consisting of dimethyldimethoxysilane, ethoxydimethylsilane, isobutylmethyldimethoxysilane, and vinylmethyldimethoxysilane, and the linear type silane having the Si—O—Si link is selected from the group consisting of 1,1,3,3-tetramethyl-1,3-dimethoxydisiloxane and 1,3-dimethyl-1,1,3,3-tetramethoxydisiloxane.

8. The precursor of claim 1, wherein the carbosilane comprises a structure represented by a formula: 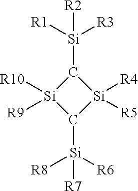
where Si represents a silicon atom, C represents a carbon atom, and each of R1-R10 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

9. The precursor of claim 1, wherein the carbosilane comprises a structure represented by a formula: 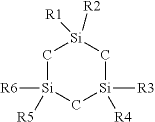
where Si represents a silicon atom, C represents a carbon atom, and each of R1-R6 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

10. A gas mixture for depositing a dielectric film in a processing chamber, the gas mixture comprising:
a precursor comprising a carbosilane comprising a Si—C—Si structure in a backbone of the precursor; and
an inert gas selected from the group consisting of argon, nitrogen, and helium.

11. The gas mixture of claim 10, further comprising an oxidizing gas selected from the group consisting of O₂, N₂O, NO₂, CO, and CO₂.

12. The gas mixture of claim 11, wherein the carbosilane comprises a structure represented by a formula: 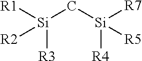
where Si represents a silicon atom, C represents a carbon atom, and each of R1-R7 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

13. The gas mixture of claim 12, wherein the carbosilane comprises a structure represented by a formula: 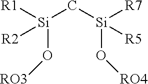
where O represents an oxygen atom, and RO2 or RO4 represents a functional group selected from a group consisting of hydrogen (H), methyl (Me), ethyl (Et), isopropyl (iPr), and tert-butyl (tBu).

14. The gas mixture of claim 11, wherein the carbosilane comprises a structure represented by a formula: 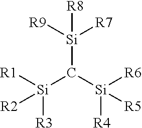
where Si represents a silicon atom, C represents a carbon atom, and each of R1-R9 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

15. The gas mixture of claim 11, wherein the carbosilane comprises a structure represented by a formula: 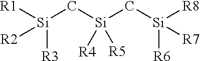
where Si represents a silicon atom, C represents a carbon atom, and each of R1-R8 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

16. The gas mixture of claim 11, wherein the carbosilane comprises a structure represented by a formula: 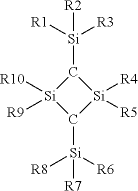
where Si represents a silicon atom, C represents a carbon atom, and each of R1-R10 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

17. The gas mixture of claim 11, wherein the carbosilane comprises a structure represented by a formula: 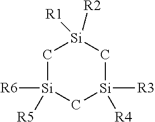
where Si represents a silicon atom, C represents a carbon atom, and each of R1-R6 represents a functional group selected from a group consisting of hydrogen (H), methyl (Me), methoxy (OMe), ethyl (Et), ethoxy (OEt), isopropyl (iPr), isoproproxy (OiPr), and tert-butyl (tBu).

18. A method of depositing a dielectric film in a processing chamber, the method comprising:
disposing a substrate on a susceptor disposed within a processing chamber;
controlling a pressure level and a temperature of the processing chamber;
delivering an RF power into the processing chamber;
providing a precursor-containing gas mixture into the processing chamber, wherein the precursor-containing gas mixture comprises:
a precursor comprising a carbosilane comprising a Si—C—Si structure in a backbone of the precursor; and
an inert gas selected from the group consisting of argon, nitrogen, and helium; and
applying a post-deposition process to the substrate after the dielectric film is formed on the substrate.

19. The method of claim 18, further comprising:
soaking the dielectric film in a soaking gas.

20. The method of claim 19, wherein the precursor-containing gas mixture comprises an oxidizing gas selected from the group consisting of O₂, N₂O, NO₂, CO, and CO₂.
